(19) United States
(12) Patent Application Publication
(10) Pub. No.: US 2012/0241866 A1
(43) Pub. Date: Sep. 27, 2012

(54) TRANSISTOR STRUCTURE AND MANUFACTURING METHOD WHICH HAS CHANNEL EPITAXIAL EQUIPPED WITH LATERAL EPITAXIAL STRUCTURE

(75) Inventor: Hiroyuki Yamasaki, Somers, NY (US)

(73) Assignee: TOSHIBA AMERICA ELECTRONIC COMPONENTS, INC., Irvine, CA (US)

(21) Appl. No.: 13/070,561

(22) Filed: Mar. 24, 2011

(51) Int. Cl. H01L 29/772; H01L 21/336

(52) U.S. Cl. 257/368; 438/299; 257/E29.242; 257/E21.431

(57) ABSTRACT

A semiconductor device and methods of fabricating semiconductor devices are provided. Provided is an epitaxial layer equipped with a lateral epitaxial layer that can block a Shallow Trench Isolation (STI) edge from a downstream etching process step, which can result in a reduced STI divot. A method involves forming a semiconductor substrate on a source region and a drain region and forming a semiconductor region on the semiconductor substrate. The method also comprises creating at least a first isolation feature adjacent to the semiconductor region and depositing an epitaxial layer on the semiconductor region and laterally between the semiconductor region and the at least the first isolation feature.

### FIELD

The following description relates generally to semiconductor devices and methods of fabricating semiconductor devices.

### BACKGROUND

Silicon large-scale integrated circuits, among other device technologies, are being widely used to provide support for the advancements in information society. An integrated circuit can be composed of a plurality of semiconductor devices, such as transistors or the like, which can be produced according to a variety of techniques. To continuously increase integration and speed of semiconductor devices, there has been an emerging trend of continuously scaling semiconductors (e.g., reducing size and features of semiconductor devices). Reducing semiconductor and/or semiconductor feature size provides improved speed, performance, density, cost per unit, and so forth of resultant integrated circuits. However, as semiconductor devices and device features have become smaller and more advanced, conventional fabrication techniques have been limited in their ability to produce finely defined features. Moreover, scaling limitations are introduced as semiconductors continue to scale down.

By way of example, various techniques facilitate scaling of integrated circuits. One technique is shallow trench isolation, which is an integrated circuit feature that prevents electrical current leakage between adjacent semiconductor devices. Conventional shallow trench isolation fabrication can include depositing a pad oxide and a protective nitride layer over a semiconductor substrate. An opening can be formed in the protective nitride layer and the semiconductor substrate can be etched to form a trench. The trench can be filled with a dielectric, such as silicon dioxide for example. Planarization can occur followed by removal of the protective nitride and pad oxide. Subsequently, active areas for semiconductor devices can be developed.

Another technique involves adjusting a threshold voltage of a transistor (e.g., a metal-oxide-semiconductor field effect transistor (MOSFET) and in particular a high-K/metal MOSFET) by introducing a mismatched semiconductor lattice on top of the substrate by way of epitaxy. Introduction of an epitaxial layer also introduces strain to a silicon lattice which increases carrier (e.g., electron and/or hole) mobility to facilitate scaling. Epitaxy is a process involving growing a single-crystalline film of material on a single-crystalline substrate or wafer.

Depositing an epitaxial layer on an active area adjacent to a shallow trench isolation feature involves masking, epitaxial growth, and cleaning steps. During such cleaning steps, portions of the shallow trench isolation feature are isotropically removed leaving a void or divot in the insulating material. Divots can introduce current leakage and/or shorting. As divots increase is size and/or depth, increased degradation due to junction leakage can result. Accordingly, it would be desirable to implement techniques for producing semiconductor devices having epitaxial layers with reduced divot formation.

### BRIEF DESCRIPTION OF THE DRAWINGS

FIGS. 1A and 1B illustrate representative block diagrams of a non-lateral epitaxial process and a lateral epitaxial process, according to an aspect.

FIGS. 2A and 2B illustrate cross-sectional images of a portion of a semiconductor device fabricated according to a conventional process.

FIGS. 3A and 3B illustrate cross-sectional images of a Static Random-Access Memory (SRAM) area of semiconductor devices fabricated according to conventional processes.

FIGS. 4A through 4C illustrate a shallow trench isolation divot formation while fabricating a semiconductor device according to a conventional process.

FIG. 5 illustrates another conventional process for forming a semiconductor device.

FIG. 6 illustrates a process for fabricating a semiconductor device, according to an aspect.

FIG. 7 illustrates an example process, according to an aspect.

FIG. 8 illustrates a process for forming a transistor, according to an aspect.

FIG. 9 illustrates a semiconductor device, according to an aspect.

FIG. 10 illustrates a cross section view and a top view of a semiconductor device formed according to the process shown and discussed with reference to FIG. 8.

FIG. 11 illustrates a comparison of semiconductor devices fabricated according to a conventional process and a process in accordance with the one or more disclosed aspects.

FIG. 12 illustrates a method for fabricating a semiconductor device, according to an aspect.

### DETAILED DESCRIPTION

During conventional semiconductor fabrication, a shallow trench isolation (STI) divot can gradually become larger (e.g., size and/or depth) at downstream process steps. The large STI divot can negatively impact several device properties, including Vt-W, junction leakage, and/or breakdown voltage. A large STI divot can also affect the metal gate coverage and the gate electrode etching process. To overcome the aforementioned as well as other deficiencies, the one or more disclosed aspects provide a semiconductor device comprising a transistor that has a channel epitaxial structure equipped with a lateral epitaxial structure.

In accordance with some aspects, a channel epitaxial layer equipped with lateral epitaxial structures is created. The lateral epitaxial structure can be underneath a gate electrode, wherein the gate electrode does not touch the STI edge directly. Therefore, the STI edge is protected from a channel epitaxial formation's downstream processing step. For example, the lateral epitaxial layer can block a STI edge from a downstream etching process step, which can result in a reduced STI divot. Since the distance between gate High-K dielectric layer and STI oxide can be extended, transistor Vt-W effect can also be improved.

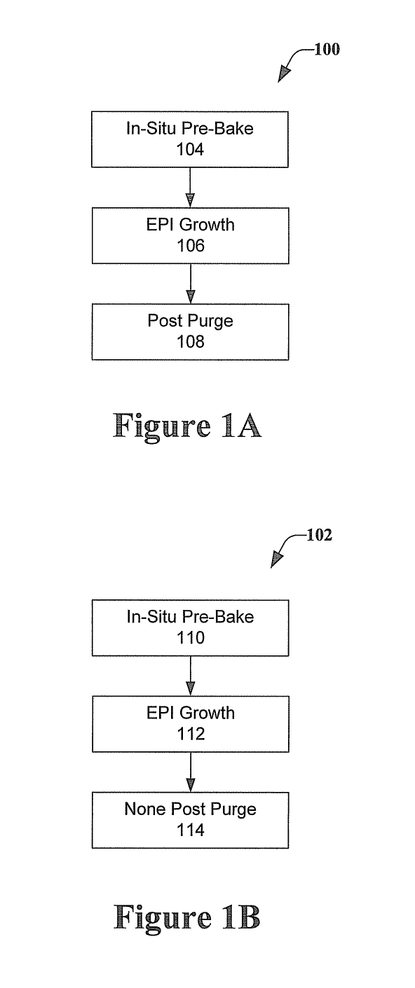

FIG. 1A illustrates a representative block diagram of a non-lateral epitaxial process 100 and FIG. 1B illustrates a representative block diagram of a lateral epitaxial process 102, according to an aspect. As shown, the non-lateral epitaxial process 100 comprises an in-situ pre-bake step 104. Next is epitaxial growth 106 followed by a post purge step 108. As shown by the lateral epitaxial process 102, an in-situ pre-bake step 110 is followed by epitaxial growth 112. Further, the lateral epitaxial structure can be formed with a post purge step optimization 114. The post purge can be processed under a temperature of around 550° C. to 650° C. with H2 atmosphere subsequent to the epitaxial deposition step. In accordance with some aspects, the lateral epitaxial structure can be formed with an abbreviation of the purge process step.

An aspect relates to a semiconductor device comprising a transistor region. The transistor region comprises a semiconductor region formed on a substrate and an isolation feature adjacent to the semiconductor region. The transistor region also comprises an epitaxial layer equipped with a lateral epitaxial layer. The epitaxial layer is grown on the semiconductor region and laterally between the semiconductor region and the isolation feature.

In an aspect, the epitaxial layer is grown laterally to protect a shallow trench isolation edge from an etching process. In another aspect, the epitaxial layer is grown laterally at a bottom of a gate electrode. In a further aspect, the epitaxial layer is grown in a drain region.

In another aspect, the epitaxial layer is grown at a bottom of a gate electrode and on a source region and a drain region, wherein the epitaxial layer is removed from at least one of the gate electrode, the source region, and the drain region. In another aspect, the epitaxial layer is formed with a laminating structure of monolayer to mitigate formation of an STI divot during wet process etching for dual gate oxide formation. In some aspects, the epitaxial layer is formed with Silicon-Germanium (SiGe), Silicon (Si), or a combination thereof.

In a further aspect, the epitaxial layer comprises a lengthwise film thickness, M1, and a cross direction film thickness, M2. The lengthwise film thickness, M1, is thicker than the cross direction film thickness, M2.

In some aspects, the isolation feature is formed by shallow trench isolation, wherein a divot is created during the shallow trench isolation. The lateral epitaxial layer restricts a height of the divot.

A further aspect relates to a semiconductor device comprising at least one isolation region formed by shallow trench isolation and a channel region. The semiconductor device also comprises a channel epitaxial layer formed on the channel region and a lateral epitaxial layer formed between the at least one isolation region and the channel region.

In an aspect, the lateral epitaxial layer is formed laterally between the at least one isolation region and the channel region to restrict formation of a divot. According to some aspects, a height of a divot is restricted.

In some aspects, an edge of the at least one isolation region is protected from a downstream processing step performed on the channel epitaxial layer. In accordance with some aspects, the lateral epitaxial layer is grown laterally at a bottom of a gate electrode.

Another aspect relates to a method for fabricating a semiconductor device. The method comprises forming a semiconductor substrate on a source region and a drain region and forming a semiconductor region on the semiconductor substrate. The method also comprises creating at least a first isolation feature adjacent the semiconductor region and depositing an epitaxial layer on the semiconductor region and laterally between the semiconductor region and the at least the first isolation feature.

In an aspect, the creating the at least the first isolation feature comprises performing shallow trench isolation and restricting a height of a divot created during the shallow trench isolation.

According to some aspects, the depositing comprises depositing the epitaxial layer laterally at a bottom of a gate electrode. In some aspects, the depositing comprises growing the epitaxial layer in the drain region. According to other aspects, the depositing comprises growing the epitaxial layer at a bottom of a gate electrode and on the source region and the drain region and removing the epitaxial layer from at least one of the gate electrode, the source region, and the drain region. In accordance with some aspects, the depositing comprises forming the epitaxial layer with Silicon-Germanium (SiGe), Silicon (Si), or a combination thereof.

The various aspects are now described with reference to the drawings. In the following description, for purposes of explanation, numerous specific details are set forth in order to provide a thorough understanding of the one or more aspects. It may be evident, however, that the various aspects may be practiced without these specific details. In other instances, well-known structures and devices are shown in block diagram form in order to facilitate describing the one or more aspects.

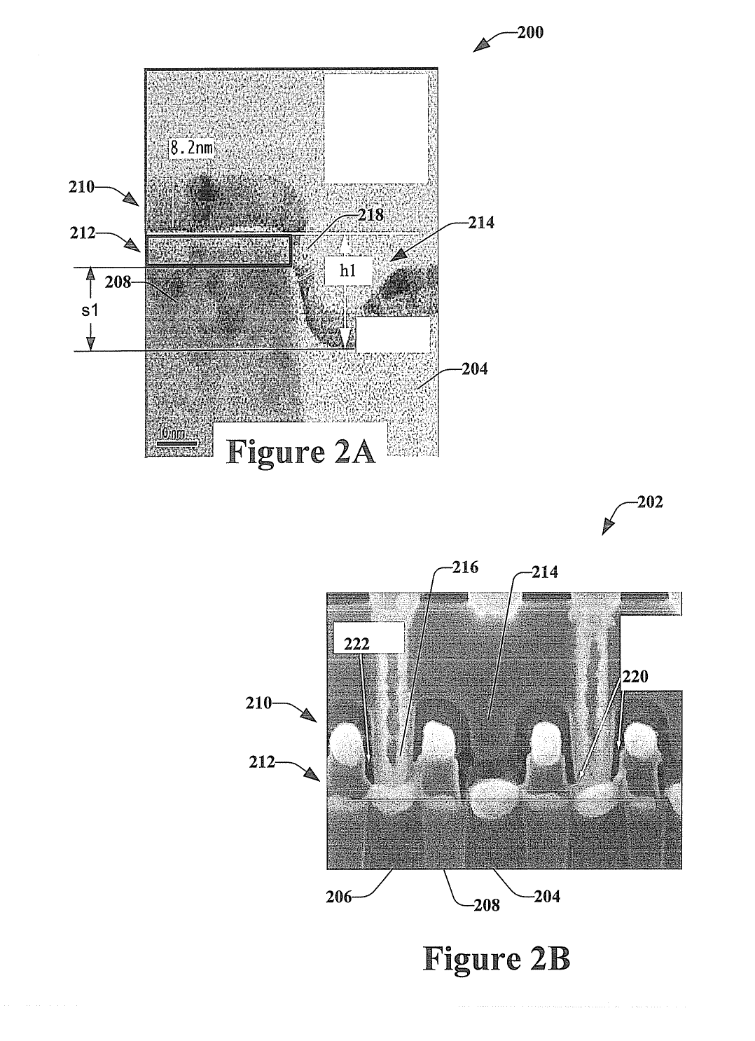

Turning now to the figures, FIGS. 2A and 2B illustrate cross-sectional images 200, 202 of a portion of a semiconductor device fabricated according to a conventional process. Depicted in images 200, 202 is a first isolation feature 204. In an example, the first isolation feature 204 can be fabricated via shallow trench isolation (STI). Between the first isolation feature 204 and a second isolation feature 206 is a silicon substrate 208. More particularly, an active region or channel region of the silicon substrate 208 is depicted in the images 200, 202. In an aspect, first isolation feature 204 and second isolation feature 206 (as well as other isolation features) operate to segregate or separate channel region of silicon substrate 208 from other active regions of silicon substrate 208. Also shown is a metal gate 210, made of Ti/TiN, and so forth.

An epitaxial layer can be formed within the region illustrated by the rectangle area (in FIG. 2A below the metal gate 210) prior to silicide formation. The epitaxial layer 212 is consumed with silicide formation, resulting in a silicide layer. In an embodiment, the epitaxial layer 212 can be a heteropitaxial layer. For example, silicon substrate 208 can include crystalline silicon and epitaxial layer 212 can include crystalline silicon-germanium (SiGe). As the epitaxial layer 212 (e.g., SiGe layer) is on channel region or active region of silicon substrate 208, it can be denoted as a cSiGe layer.

During the process to grow epitaxial layer on the silicon substrate 208, the first isolation feature 204, the second isolation feature 206, and the silicon substrate 208, undergo a plurality of masking, etching, and/or cleaning steps. The steps can remove portions of the first isolation feature 204 and the second isolation feature 206. Removal of portions of the first isolation feature 204 and second isolation feature 206 generate a first divot 214 in the first isolation feature 204 and a second divot 216 in the second isolation feature 206. Image 200 depicts a height difference, h1, between the bottom of first divot 214 and a top of the epitaxial layer 212. In addition, when divots are large (e.g., size and/or depth), a pre-bake step of the epitaxial process (e.g., typically at 800 degrees Celsius in hydrogen atmosphere), can enhance corner rounding of the silicon substrate 208.

The bottom of the first divot 214 can be referred to as a height of the first isolation feature 204 at a corner of a junction between the first isolation feature 204 and the silicon substrate 208. In image 200, h1 is between about 21 nanometers (nm) and 26 nm. In an example, h1 is approximately 21.4 nm. However, it is to be appreciated that the height difference can vary depending on the particular processing methods and systems employed to fabricate the semiconductor device. In another embodiment, a height difference between a bottom of the first divot 214 and the interface of the silicon substrate 208 and the epitaxial layer 212 can be equal to height difference, s1. However, it is to be appreciated that variations in depths of divots can be exhibited.

As the height difference, h1 (or s1), increases, junction leakage also increases. According to an embodiment, the semiconductor device depicted in image 200 can comprise a p-type field effect transistor (PFET). Accordingly, the junction leakage can occur at a P+/P− Well junction. Such a PFET semiconductor device can be incorporated into a static random access memory (SRAM) device, for example. Thus, conventional processes can create a STI divot underneath the gate dielectric due to the channel epitaxial formation process.

Further, as the height difference, h1 (or s1), increases there can be degradation of break down voltage due to the large STI divot. Further, there can be degradation of metal gate coverage at active device area or active area edge. For example, as shown at 218 the metal gate 210 (e.g., Ti, TiN, and so forth) is broken (e.g., electrical field is increasing at an active area corner). There can also be degradation of a gate electrode profile (as shown in image 202) due to the large STI divot. Additionally, there can be degradation of Vt-W due to the large STI divot. Further, as illustrated at 220, silicide does not extend the full width of active device area—gate structure blocking it on both sides. Additionally, as shown at 222, silicide of the active area touches Si of the gate electrode.

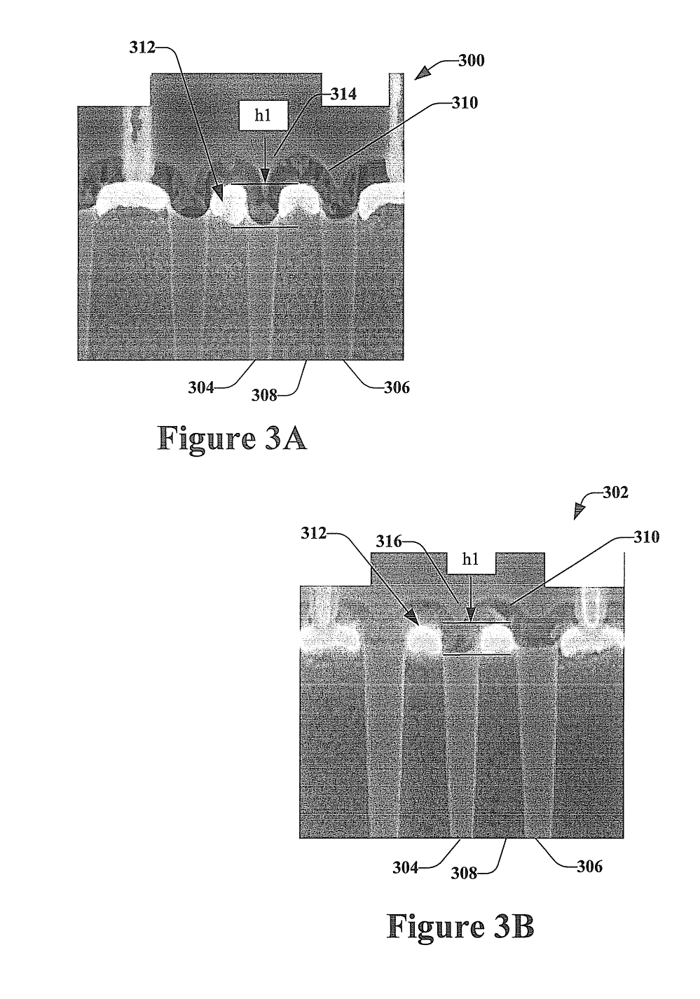

FIGS. 3A and 3B illustrate cross-sectional images 300, 302 of a Static Random-Access Memory (SRAM) area of semiconductor devices fabricated according to conventional processes. Depicted in images 300, 302 are respective first isolation features 304 and second isolation features 306 and silicon substrates 308 there between. Also depicted is a nitride liner 310. An epitaxial layer 312 is formed prior to silicide formation. The epitaxial layer 312 is consumed with silicide formation.

As shown in image 300 a conventional process can form a large divot 312. In an example, the divot 314 has a height, h1, which can be about 36 nm. FIG. 3B illustrates a conventional process that forms a small divot 314. In an example, the divot 316 has a height, h1, which can be about 26 nm. The divots 314, 316 have increased silicide thickness, which can lead to degradation of junction leakage and break down voltage, as well as other problems, which can be overcome with the one or more aspects disclosed herein.

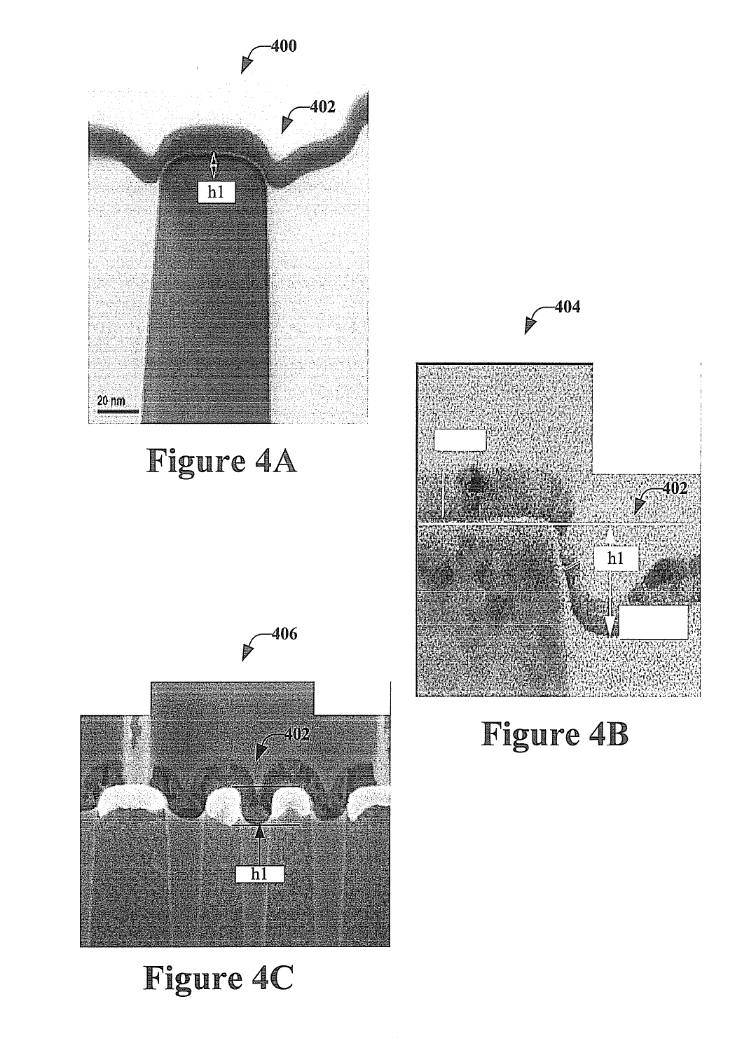

FIGS. 4A through 4C illustrate a shallow trench isolation (STI) divot formation while fabricating a semiconductor device according to a conventional process. At FIG. 4A is an image 400 of the device during a post epitaxial process, wherein a height, h1, of a divot 402 is approximately 11 nm. At FIG. 4B is an image 404 of the device after post gate electrode formation, wherein a height, h1, of the divot 402 increases to between approximately 21 to 26 nm. FIG. 4C is an image 406 of the device, wherein the height, h1, of the divot 402 increases to about 36 nm. Thus, as illustrated, the STI divot starts to increase from channel epitaxial formation and is enhanced (e.g., height increases) with subsequent wet steps (e.g., dual gate oxide formation) until silicide formation. In accordance with some aspects, the STI divot is increased with wet steps and dry etching steps (e.g., spacer formation, and so forth).

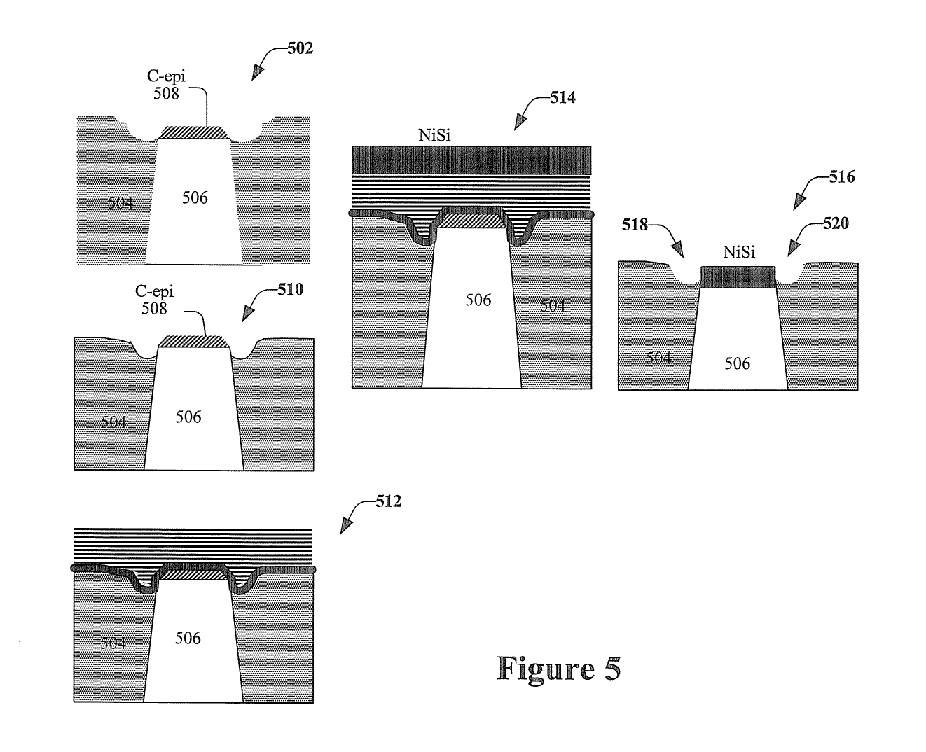

FIG. 5 illustrates another conventional process for forming a semiconductor device. Depicted at 502 is channel epitaxial formation. Isolations regions (STI 504) and a channel area or active area 506 are shown as well as a channel epitaxial layer 508 (C-epi). Shown at 510 is the semiconductor device after a dual gate oxide formation wet process. Depicted at 512 is post gate electrode formation. Spacer to silicide formation is shown at a cross section underneath gate 514 and at a cross section not underneath gate 516.

As illustrated in FIG. 5, degradation of metal gate coverage at an active area edge and gate electrode profile and Vt-W is due to the large STI divot 518, 520. Large STI divot existence with source drain implant and silicide formation can lead to a degradation of junction leakage and break down voltage, as well as other problems.

According to conventional processes, to provide a transistor that has a channel epitaxial structure, the STI divot gradually becomes larger (e.g., increased height) at a downstream process step. However, with the one or more disclosed aspects, a lateral epitaxial layer can block a STI edge from downstream etching process steps and, therefore, the STI divot height can be reduced or restricted, as compared to conventional processes. Because of the lateral epitaxial structure, the gate electrode does not touch the STI edge directory so transistor Vt-W effect can be improved. Further, since the distance between gate High-K dielectric layer and STI oxide can be extended with the lateral epi structure, transistor Vt-W effect can be improved.

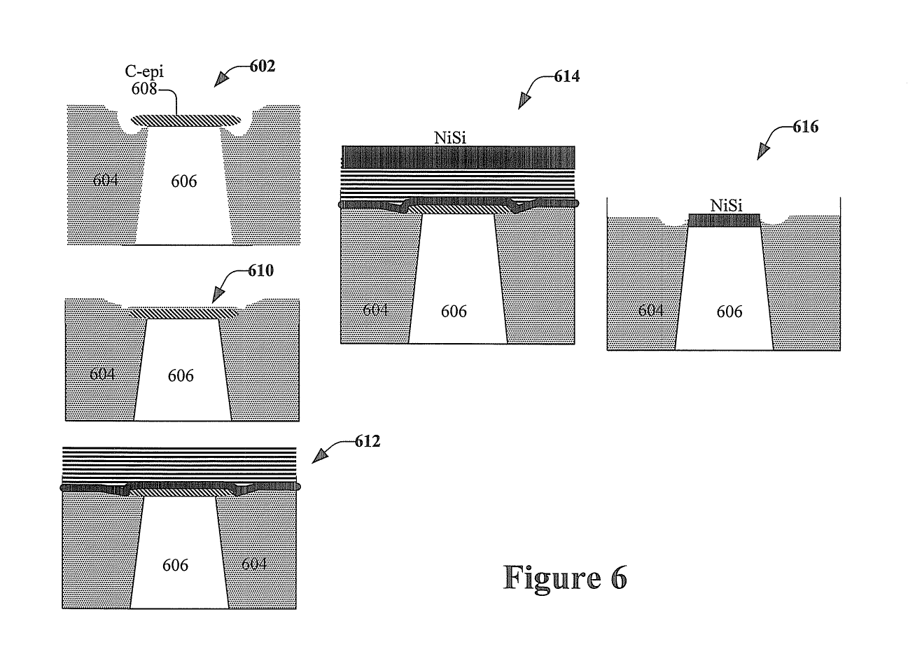

FIG. 6 illustrates a process for fabricating a semiconductor device, according to an aspect. An increase in the height of an STI divot is mitigated with a lateral epitaxial layer. Depicted at 602 is channel epitaxial formation. The channel epitaxial formation includes lateral epitaxial formation. In an aspect, the channel epitaxial layer is formed with a laminating structure of monolayer to mitigate formation of an STI divot during wet process etching for dual gate oxide formation. In some aspects, the channel epitaxial layer is formed with Silicon-Germanium (SiGe), Silicon (Si), or a combination thereof.

Isolation features 604 (STI) and channel areas or active areas 606 are shown as well as a channel epitaxial layer 608 (C-epi). Also shown is the semiconductor device after chemical vapor deposition 610 (e.g. CVD process). Depicted at 612 is the device after post gate electrode formation. Spacer to silicide formation is shown at a cross section underneath gate 614 and at a cross section not underneath gate 616.

For example, a PFET, such as a pull-up transistor of a SRAM cell, can be fabricated via epitaxy. In particular, an epitaxial layer 608 can be grown on a silicon substrate. To grow an epitaxial layer 608, a first step is to etch an oxide layer to expose a surface (e.g., a channel region) of the silicon substrate. In an embodiment, a wet etch process 610 removes the oxide layer. With a wet etch process 610, portions of an isolation feature 604 can be isotropically removed. After the wet etch process 610, an oxide layer is removed and an isolation feature 604 is partially removed. More particularly, isolation feature 604 laterally retreats during the wet etch process 610.

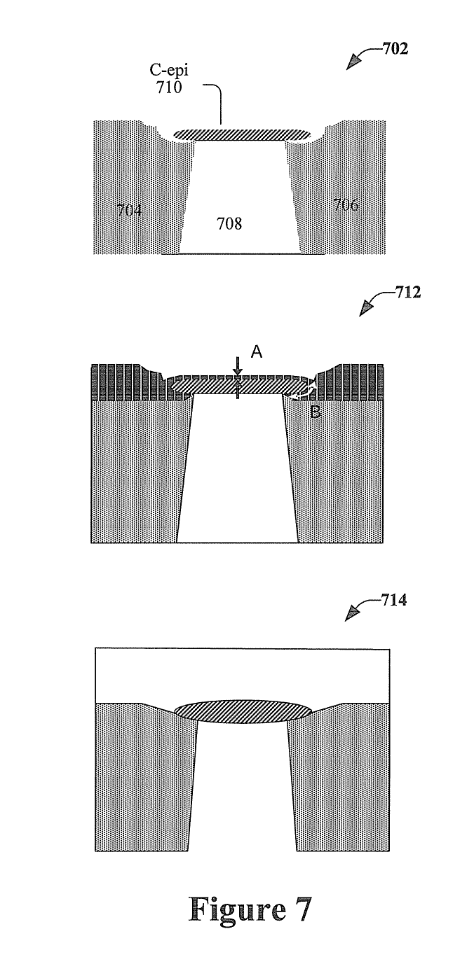

FIG. 7 illustrates an example process, according to an aspect. Illustrated at 702 is a device that comprises isolation features 704, 706 and a channel area 708. Epitaxial growth comprises forming a channel epitaxial layer 710 equipped with a lateral epitaxial structure. After channel epitaxial formation, at 712, a dummy CVD is deposited and a space between the lateral epitaxial structure and STI divot can be filled with the CVD. Due to the thickness delta between A (indicated by the arrow at 712) and B (indicated by the curved arrow at 712), the STI divot portion can be protected from wet etching, at 714. Therefore, the CVD can mitigate STI divot increasing from wet process etching for dual gate oxide formation and so forth. Further, the STI divot can be protected from dry etching process for spacer formation.

Prior to epitaxial growth, a pre-clean step facilitates improving the surface of the silicon substrate. For successful epitaxial growth, an amount of defects and contaminants on the channel region of silicon substrate should be minimized. Pre-cleaning can include subjecting a portion to an RCA clean, or other suitable cleaning, followed by a hydrofluoric acid dip and a deionized water rinse. However, it is to be appreciated that other pre-clean processes can be employed to prepare a surface of silicon substrate for epitaxy. After pre-cleaning, the portion can undergo a pre-bake process. During pre-bake, the portion is subjected to a hydrogen atmosphere and heated. While the pre-cleaning and/or pre-baking steps provide an optimal surface for epitaxial growth, these steps can erode the integrity of isolation features. For example, pre-cleaning and pre-baking can lead to formation of a divot in isolation feature.

The lateral epitaxial can be removed with spacer formation and leaved. Advantages of the disclosed aspects include improvement of metal gate coverage at an active area edge and gate electrode profile and Vt-W due to the mitigation of the height of an STI divot with lateral epitaxial underneath the gate. Another advantage is that Vt-W is improved by the increased distance between STI oxide and high-K gate dielectric underneath gate with lateral epitaxial. A further advantage is that junction leakage and break down voltage are improved by mitigating a height of the STI divot with lateral epitaxial.

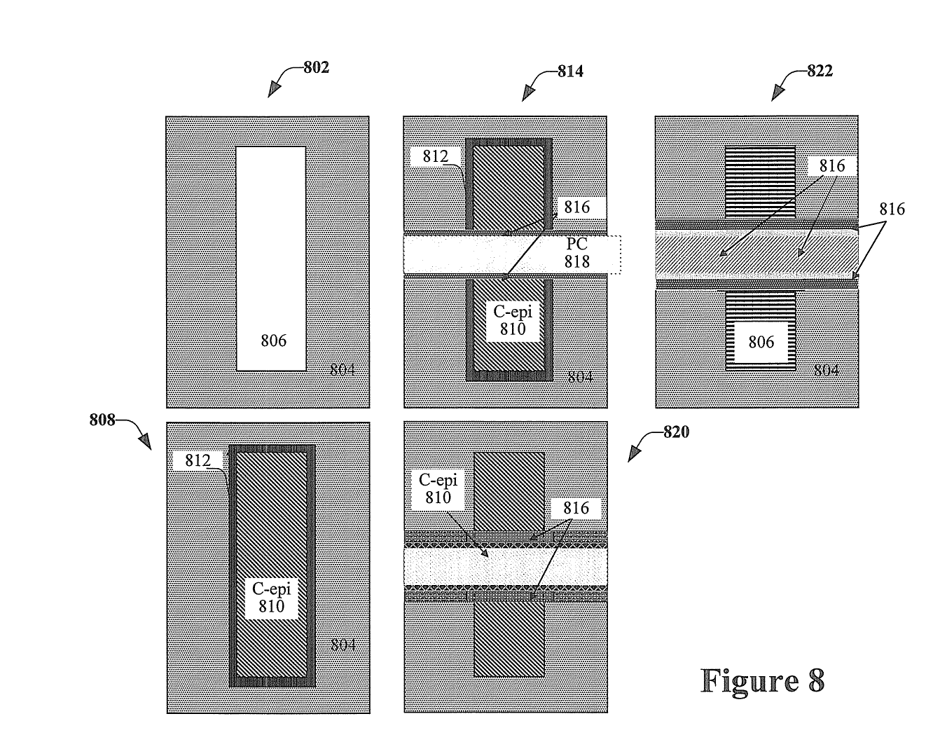

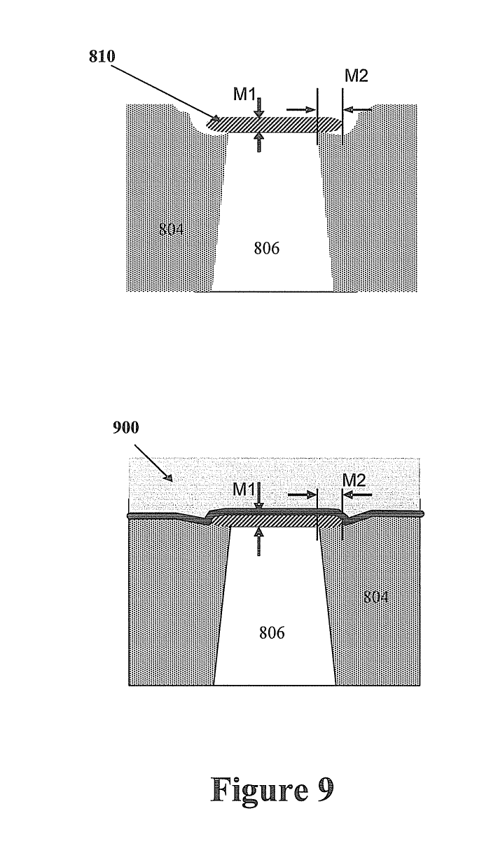

FIG. 8 illustrates a process for forming a transistor, according to an aspect. At 802 is depicted shallow trench isolation 804 (STI), Well, and channel formation 806 (active area). At 808 is channel epitaxial 810 formation (C-epi) and lateral epitaxial 812 formation on the channel. In an aspect, as illustrated in FIG. 9, the epitaxial layer 810 comprises a lengthwise film thickness, M1, and a cross direction film thickness, M2, wherein the lengthwise film thickness, M1, is thicker than the cross direction film thickness, M2. According to some aspects, an isolation feature is formed by shallow trench isolation, wherein a divot is created during the shallow trench isolation, wherein the lateral epitaxial layer restricts a height of the divot, as shown at the gate electrode 900.

Referring again to FIG. 8, depicted at 814 is offset spacer formation and shown are the offset spacer 816 and a gate structure 818. Lateral epitaxial 812 exists underneath the offset spacer 816. STI recess next to an active device area can be mitigated by lateral epitaxial as discussed herein. Shown at 820, is spacer formation. Lateral epitaxial 812 can be removed with spacer formation. Depicted, at 822, is silicide formation.

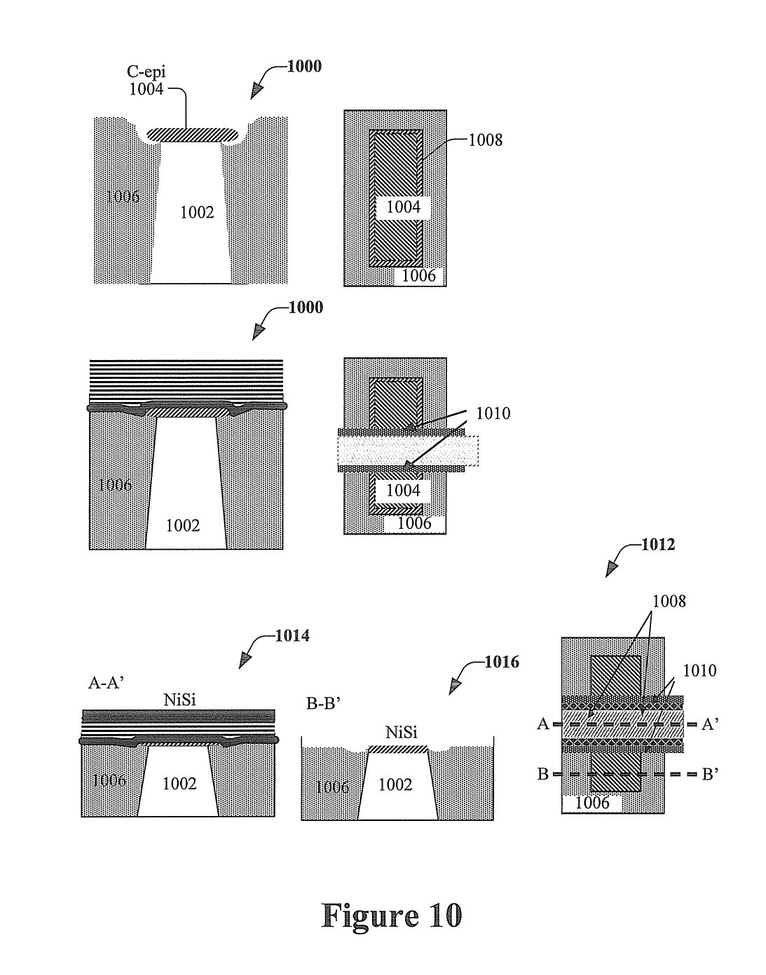

FIG. 10 illustrates a cross section view and a top view of a semiconductor device 1000 formed according to the process shown and discussed with reference to FIG. 8. The semiconductor device 1000 comprises a transistor region that includes a semiconductor region 1002 formed on a substrate and an epitaxial layer 1004 grown on the semiconductor region 1002. The transistor region also comprises at least one isolation region 1006 adjacent to the semiconductor region 1002 wherein a lateral epitaxial layer 1008 is grown laterally between the semiconductor region 1002 and the at least one isolation region 1006. A gate offset spacer 1010 is formed on the semiconductor device 1000.

A cross-section view along line A-A′ of image 1012 is shown at 1014 (underneath gate). A cross-section view along line B-B′ of image 1012 is shown at 1016 (not underneath gate). As shown, lateral epitaxial on S/D (along line B-B′) can be removed.

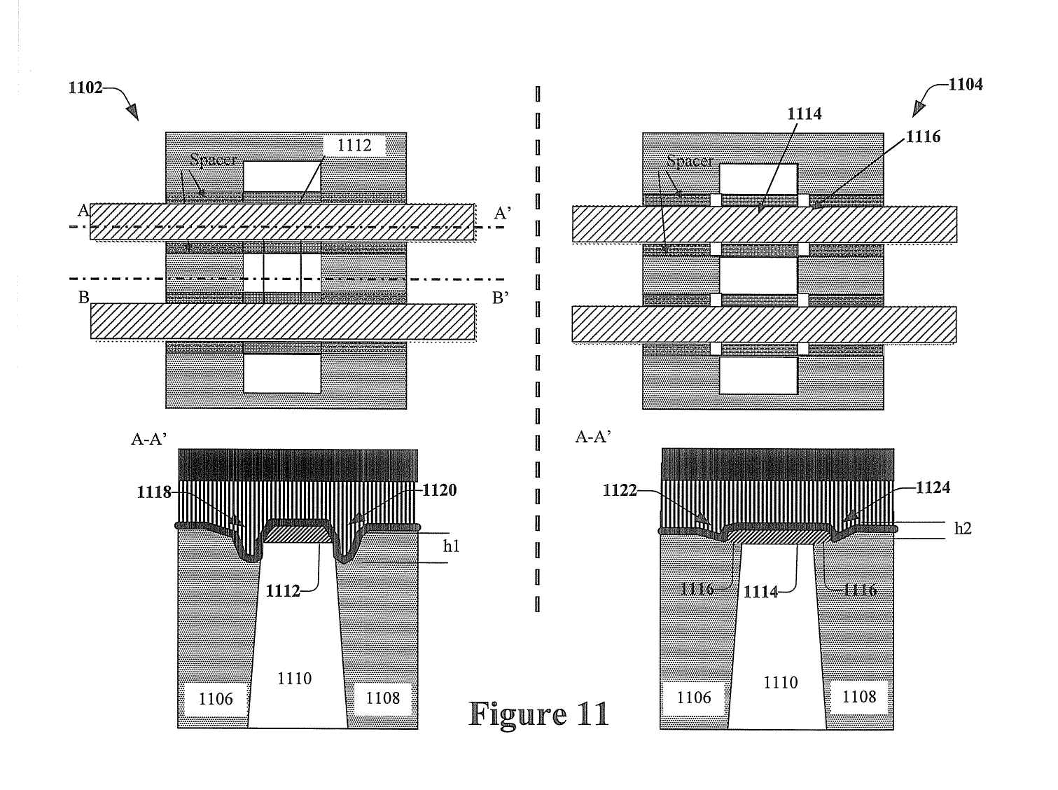

FIG. 11 illustrates a comparison of semiconductor devices fabricated according to a conventional process and a process in accordance with the one or more disclosed aspects. Depicted on the left side is a semiconductor device 1102 formed according to a conventional process. Depicted on the right side is a semiconductor device 1104 formed according to the one or more disclosed aspects. Both semiconductor devices 1102, 1104 comprise respective first isolation features 1106 and second isolation features 1108. In an example, the first isolation feature 1106 and the second isolation feature 1108 are fabricated via shallow trench isolation (STI). Between the first isolation feature 1106 and the second isolation feature 1108 is a silicon substrate 1110. More particularly, an active region or channel region of the silicon substrate 1110 is depicted in the figure.

In accordance with some aspects, an epitaxial layer can be located on top of the silicon substrate 1110. For example, an epitaxial layer 1112 of the semiconductor device 1102 fabricated according to a conventional process is on the silicon substrate 1110. The semiconductor device 1104 fabricated according to the disclosed aspects comprises an epitaxial layer 1114 and a lateral epitaxial layer 1116. The lateral epitaxial layer 1116 can block a STI edge from a downstream etching process step, which can result in a reduced divot size as discussed in further detail below.

During the process to grow epitaxial layer 1112 or epitaxial layer 1114 and lateral epitaxial layer 1116, first isolation feature 1106 and second isolation feature 1108 undergo a plurality of masking, etching, and/or cleaning steps. The steps can remove portions of the first isolation feature 1106 and the second isolation feature 1108.

As shown by the semiconductor device 1102 formed according to a conventional process, removal of portions of the first isolation feature 1106 and second isolation feature 1108 generate a first divot 1118 in first isolation feature 1106 and a second divot 1120 in the second isolation feature 1108. The semiconductor device 1104 formed according to the disclosed aspects, comprises a first divot 1122 generated by removal of portions of the first isolation feature 1106 and a second divot 1124 generated by removal of portions of the second isolation feature 1108. Although referred to as distinct divots, the first divot 1118, 1122 and second divot 1120, 1124 can consist of disparate portions of a single divot forming a ring.

A height difference, h1, is created between the bottom of the first divot 1118 and the second divot 1120 and the epitaxial layer 1112. Further, a height difference, h2, between the bottom of the first divot 1122 and the second divot 1124 and the epitaxial layer 1112 is formed. As can be seen, the height difference, h1, is larger for the semiconductor device 1102 fabricated according to the conventional process as compared to the height difference, h2, formed in the semiconductor device 1104 fabricated according to the one or more disclosed aspects.

As the height difference increases, junction leakage also increases. Further, as the height difference increases, there can be degradation of break down voltage due to the large STI divot. Further, there can be degradation of metal gate coverage at an active device area edge. There can also be degradation of a gate electrode profile due to the large STI divot. Additionally, there can be degradation of Vt-W due to the large STI divot.

The smaller height difference, h2, created with the one or more disclosed aspects provides improvement of metal gate coverage at an active area edge and gate electrode profile and Vt-W due to the reducing STI divot with lateral epitaxial underneath the gate. Vt-W is improved by the increased distance between STI oxide and high-K gate dielectric underneath gate with lateral epitaxial. Because Vt-W can deteriorate with oxidation of high-K gate dielectric by oxygen from STI oxide. Junction leakage and break down voltage are improved by reducing a size of a STI divot with lateral epitaxial.

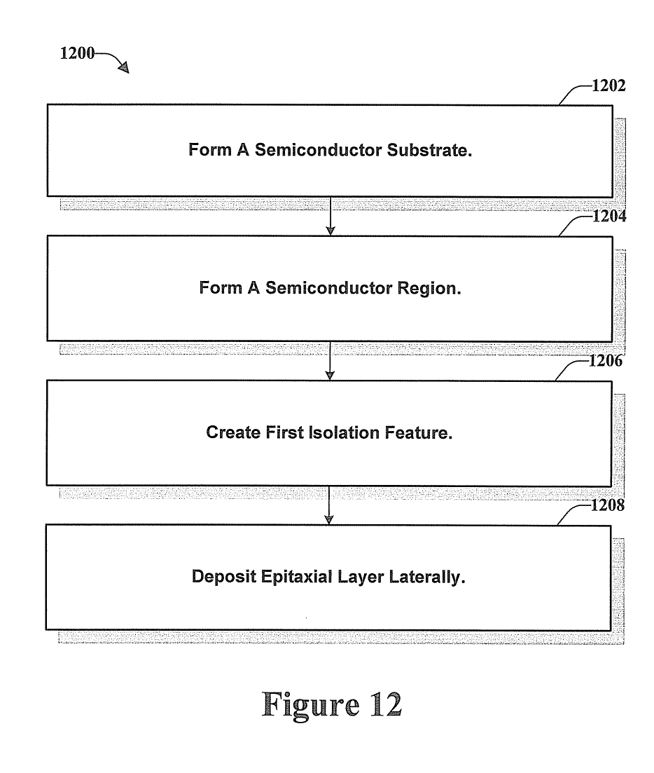

FIG. 12 illustrates a method 1200 for fabricating a semiconductor device, according to an aspect. Method 1200 starts, at 1202, when a semiconductor substrate is formed on a source region and a drain region. At 1204, a semiconductor region is formed on the semiconductor substrate. At least a first isolation features is created, at 1206. The first isolation feature is created adjacent the semiconductor region. In accordance with some aspects, creating the first isolation feature comprises performing shallow trench isolation.

At 1208, an epitaxial layer is deposited on the semiconductor region and laterally between the semiconductor region and the at least the first isolation feature. According to some aspects, the depositing comprises depositing the epitaxial layer laterally at a bottom of a gate electrode. In some aspects, the depositing comprises growing the epitaxial layer in the drain region. In other aspects, the depositing comprises growing the epitaxial layer at a bottom of a gate electrode and on the source region and the drain region and removing the epitaxial layer from at least one of the gate electrode, the source region, and the drain region. In some aspects, the depositing comprises forming the epitaxial layer with Silicon-Germanium (SiGe), Silicon (Si), or a combination thereof.

With respect to any figure or numerical range for a given characteristic, a figure or a parameter from one range may be combined with another figure or a parameter from a different range for the same characteristic to generate a numerical range. All numbers, values and/or expressions referring to quantities of ingredients, reaction conditions, etc., used in the specification and claims are to be understood as modified in all instances by the term “about.”

While, for purposes of simplicity of explanation, methods are shown and described as a series of blocks, it is to be understood and appreciated that the disclosed aspects are not limited by the number or order of blocks, as some blocks may occur in different orders and/or at substantially the same time with other blocks from what is depicted and described herein. Moreover, not all illustrated blocks may be required to implement methods described herein.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

What is claimed is:

1. A semiconductor device, comprising:
a transistor region comprising:
a semiconductor region formed on a substrate;
an isolation feature adjacent to the semiconductor region; and
an epitaxial layer equipped with a lateral epitaxial layer, wherein the epitaxial layer is grown on the semiconductor region and laterally between the semiconductor region and the isolation feature.

2. The semiconductor device of claim 1, the epitaxial layer is grown laterally to protect a shallow trench isolation edge from an etching process.

3. The semiconductor device of claim 1, wherein the epitaxial layer is grown laterally at a bottom of a gate electrode.

4. The semiconductor device of claim 1, wherein the epitaxial layer is grown in a drain region.

5. The semiconductor device of claim 1, wherein the epitaxial layer is grown at a bottom of a gate electrode and on a source region and a drain region, wherein the epitaxial layer is removed from at least one of the gate electrode, the source region, and the drain region.

6. The semiconductor device of claim 1, wherein the epitaxial layer comprises a lengthwise film thickness, M1, and a cross direction film thickness, M2, wherein the lengthwise film thickness, M1, is thicker than the cross direction film thickness, M2.

7. The semiconductor device of claim 1, wherein the isolation feature is formed by shallow trench isolation, where a divot is created during the shallow trench isolation, and wherein the lateral epitaxial layer restricts a height of the divot.

8. The semiconductor device of claim 1, wherein the epitaxial layer is formed with a laminating structure of monolayer to mitigate formation of an STI divot during wet process etching for dual gate oxide formation.

9. The semiconductor device of claim 1, wherein the epitaxial layer is formed with Silicon-Germanium (SiGe), Silicon (Si), or a combination thereof.

10. A semiconductor device, comprising:
at least one isolation region formed by shallow trench isolation;
a channel region;
a channel epitaxial layer formed on the channel region; and
a lateral epitaxial layer formed between the at least one isolation region and the channel region.

11. The semiconductor device of claim 10, wherein the lateral epitaxial layer is formed laterally between the at least one isolation region and the channel region to restrict formation of a divot.

12. The semiconductor device of claim 10, wherein a height of a divot is restricted.

13. The semiconductor device of claim 10, wherein an edge of the at least one isolation region is protected from a downstream processing step performed on the channel epitaxial layer.

14. The semiconductor device of claim 10, wherein the lateral epitaxial layer is grown laterally at a bottom of a gate electrode.

15. A method for fabricating a semiconductor device, comprising:
forming a semiconductor substrate on a source region and a drain region;
forming a semiconductor region on the semiconductor substrate;
creating at least a first isolation feature adjacent to the semiconductor region; and
depositing an epitaxial layer on the semiconductor region and laterally between the semiconductor region and the at least the first isolation feature.

16. The method of claim 15, wherein the creating the at least the first isolation feature comprises:
performing shallow trench isolation; and
restricting a height of a divot created during the performing shallow trench isolation.

17. The method of claim 15, wherein the depositing comprises depositing the epitaxial layer laterally at a bottom of a gate electrode.

18. The method of claim 15, wherein the depositing comprises growing the epitaxial layer in the drain region.

19. The method of claim 15, wherein the depositing comprises:
growing the epitaxial layer at a bottom of a gate electrode and on the source region and the drain region; and
removing the epitaxial layer from at least one of the gate electrode, the source region, and the drain region.

20. The method of claim 15, wherein the depositing comprises forming the epitaxial layer with Silicon-Germanium (SiGe), Silicon (Si), or a combination thereof.
